(19) United States
(12) Patent Application Publication
(10) Pub. No.: US 2010/0231252 A1
(43) Pub. Date: Sep. 16, 2010

(54) TESTABLE INTEGRATED CIRCUIT AND IC TEST METHOD

(75) Inventors: Sandeepkumar Goel, Eindhoven (NL); Jose De Jesus Pineda De Gyvez, Eindhoven (NL); Rinze L.M.P. Meijer, Herkenbosch (NL)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/160,409

(22) PCT Filed: Jan. 5, 2007
(86) PCT No.: PCT/IB07/50036

§ 371 Date: Jul. 9, 2008

(30) Foreign Application Priority Data
Jan. 9, 2006 (EP) 06100148.3

(51) Int. Cl. G01R 31/26

(52) U.S. Cl. 324/765

(57) ABSTRACT

An integrated circuit (200) comprises a functional block (130) conductively coupled to a supply rail (110) via one or more switches (115). The IC further comprises selection means (220) responsive to a test enable signal for activating the one or more switches (115) in a test mode of the IC and evaluation means such as a comparator (230) having a first input coupled to a reference signal source (215) and having a second input coupled to a node (225) between the one or more switches (115) and the functional block (130) for evaluating the behaviour of the one or more switches (115) based on the reference signal and a signal from the node (225). Thus, the present invention provides a design for testability solution for testing power switches.

The present invention relates to an integrated circuit (IC) comprising a functional block conductively coupled to a supply rail via switching means, and to a method for testing such an IC.

Nowadays, ICs are typically capable of performing many functions. Separate functions may be contained in separate functional blocks, as for instance is the case in systems on chip (SoCs). The ongoing increase in IC complexity is typically associated with an increase in power consumption by the IC. Part of this power consumption may be caused by functional blocks that are powered up but not active. This may be detrimental to the lifetime of a battery used to power the IC.

A solution to this problem is to place switches, e.g. power transistors, between a functional block and its supply rail. A controller activates the switches when the functionality of the functional block is required. This way, inactive functional blocks are kept in a powered down state, thus reducing the power consumption of the IC.

Such switches need to be tested in the manufacturing stages of the IC to ensure its correct functioning. A solution for testing switches has been proposed in PCT patent application WO01/181937. Two switching transistors under control of a test controller are placed in parallel between two external terminals of the IC. During test, three measurements, one with both transistors switched on and two with one of the transistors switched on, are performed and the resistance of the switching transistors is extracted from the measurements. This resistance gives an indication whether or not the transistors operate according to specification.

However, a drawback of this invention is that it is limited to switches that, at least during test, are accessible via external terminals. This is not always the case for switches that are coupled between a supply rail and a functional block. Moreover, the prior art solution requires the presence of switches in parallel, which is also a limitation to the applicability of this method.

The present invention seeks to provide an IC and a test method for such an IC that, inter alia, does not require the presence of parallel switches between external terminals for testing such switches.

According to a first aspect of the present invention, there is provided an IC according to the opening paragraph, the IC further comprising selection means responsive to a test enable signal for activating the switching means, and evaluation means having a first input coupled to a reference signal source and having a second input coupled to a node between the switching means and the functional block for evaluating the behaviour of the switching means based on the reference signal and a signal from the node. The present invention provides a design for testability (DfT) solution on the IC, thus obviating the need for direct accessibility of the switching means, e.g. a switch such as an nMOS or pMOS transistor, or a plurality of switches in parallel, via external connectors. The use of a reference signal facilitates the on-chip analysis of the switching means.

In a preferred embodiment, the evaluation means comprise a comparator for comparing the reference signal to the signal from the node. Such a comparator may be implemented as a logic gate, e.g. an exclusive logic gate such as an XOR gate. In case the reference signal and a test activation signal provided by the selection means are the same signal, the logic gate cannot uncover faults that are sensitized by the test activation signal being false. To this end, a further test point coupled to the node may be added, such as a further logic gate comprising a first input coupled to the node, a second input coupled to a further reference signal source, and an output coupled to an input of the logic gate. This test point facilitates the detection of those faults.

Alternatively, the evaluation means may comprise a shift register coupled to an output of the integrated circuit to facilitate off-chip evaluation. Preferably, the shift register is an IEEE 1149.1 or IEEE 1500 compliant shift register under control of a test access port (TAP) controller that is compliant with these standards.

In an area-efficient embodiment, the selection means may comprise a multiplexer having a first input for receiving a test activation signal, a second input for receiving a functional activation signal and an output coupled to the selection means. In case the switching means comprise a plurality of transistors in parallel between the supply rail and the functional block, the selection means may comprise a plurality of multiplexers each responsive to the test enable signal, each multiplexer having a first input for receiving a test activation signal, a second input for receiving a functional activation signal and an output coupled to a subset of the plurality of transistors. This way, if a fault is detected, it can be assigned to a subset of the transistors, thus providing more detailed information about the location of the fault.

The IC further comprises test configuration means for providing the test enable signal to the selection means, the test configuration means comprising the reference signal source. This way, the reference signal can also be configured. Such test configuration means may be implemented as a shift register, preferably an IEEE 1149.1 or IEEE 1500 compliant shift register, thus providing facile access to the test arrangement of the IC.

Alternatively, in cases where the integrated circuit comprises a plurality of functional blocks, each coupled to the supply rail via respective switching means, the selection means may comprise a controller for selecting subsets of the respective switching means during functional mode of the integrated circuit, the controller being responsive to a bit pattern for selecting said subsets in the integrated circuit test mode. Such a bit pattern may be provided via a test bus or a shift register, thus providing an embodiment in which the controller for the switching means in functional mode is also used for testing, which is an area efficient embodiment.

In addition to the aforementioned embodiments, the one or more functional blocks may be coupled to a further supply rail via further switching means (so-called header and footer switches). For such architectures, the integrated circuit may further comprise further selection means responsive to the test enable signal for activating the further switching means; and further evaluation means having a first input coupled to a second further reference signal source and having a second input coupled to a further node between the further switching means and the functional block for evaluating the behaviour of the further switching means based on the second further reference signal and a signal from the further node. This facilitates the testing of both the header as well as the footer switches.

The further selection means may be responsive to further test configuration means, or may be responsive to the test configuration means.

The test configuration means and the further test configuration means may be integrated in a single test configuration means, e.g. a single shift register, which has the advantage that both test configuration means can be accesses through a single channel, e.g. a single pin such as the test data input pin of a TAP.

Advantageously, the IC further comprises a test output, e.g. an output pin such as the test data output pin of a TAP, and test output selection means having a first input coupled to an output of the evaluation means, a second input coupled to an output of the further evaluation means and an output coupled to the test output. This facilitates selection of one of the evaluation means and the further evaluation means. The test output selection means may be implemented as a multiplexer responsive to either the selection means or the further selection means.

According to another aspect of the invention, there is provided a method for testing an integrated circuit comprising a functional block conductively coupled to a supply rail via switching means, selection means responsive to a test enable signal for activating the switching means; and evaluation means having a first input coupled to a reference signal source and having a second input coupled to a node between the switching means and the functional block for evaluating the switching means based on the reference signal and a signal from the node, the method comprising providing the test enable signal to the selection means; providing the reference signal to the evaluation means; retrieving the signal from the node; and determining a test result from the reference signal and the signal from the node.

This method utilizes the design for testability architecture of the present invention, and benefits from the same advantages of this architecture. In a preferred embodiment, the step of determining said test result comprises comparing the reference signal to the signal from the node. This can be performed either on-chip or off-chip.

The invention is described in more detail and by way of non-limiting examples with reference to the accompanying drawings, wherein:

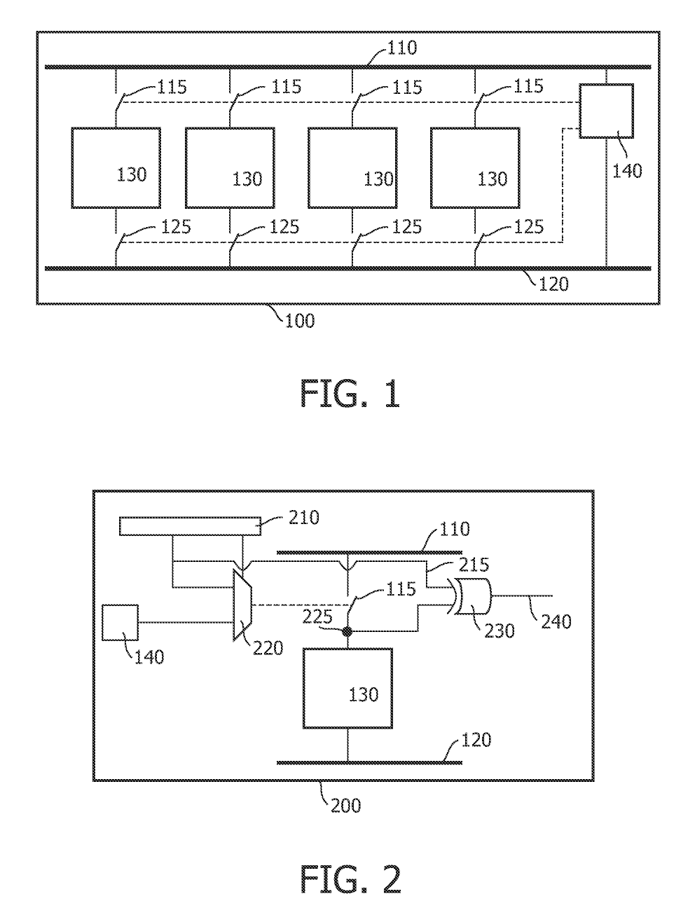

FIG. 1 shows a portion of an IC;

FIG. 2 shows a portion of an IC with an embodiment of the present invention;

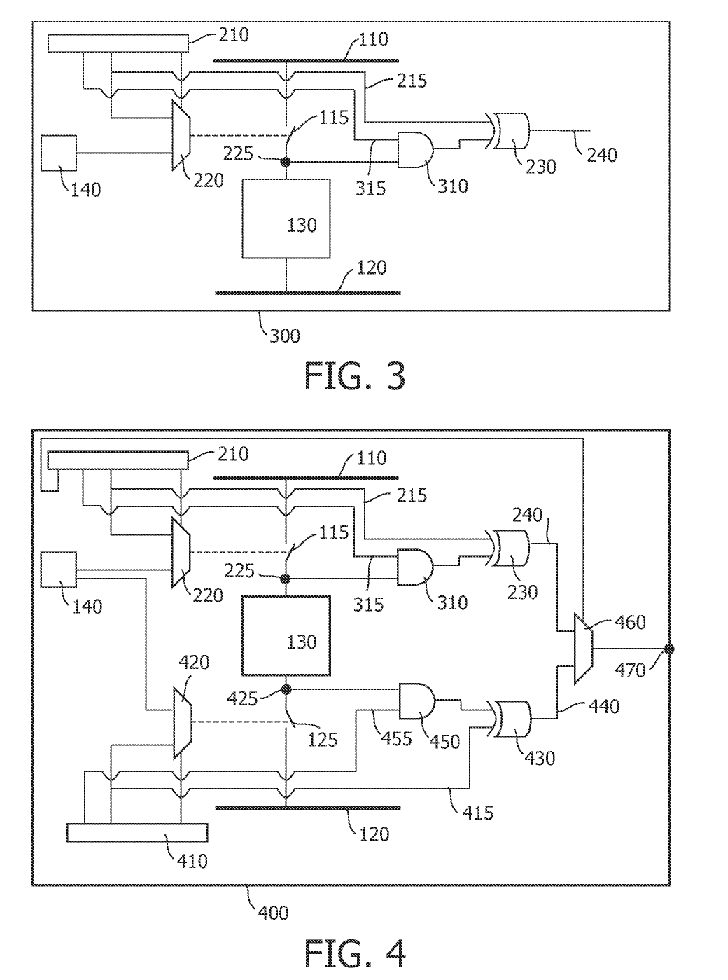

FIG. 3 shows a portion of an IC with another embodiment of the present invention;

FIG. 4 shows a portion of an IC with yet another embodiment of the present invention;

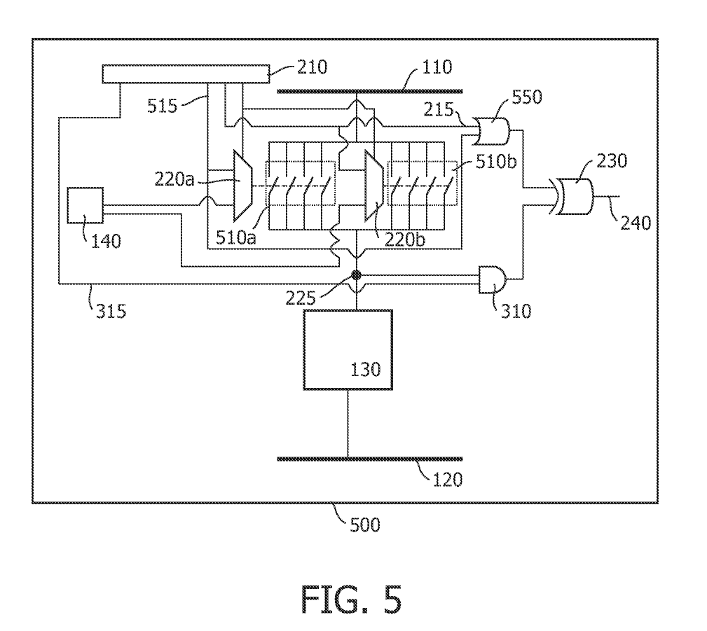

FIG. 5 shows a portion of an IC with yet another embodiment of the present invention; and

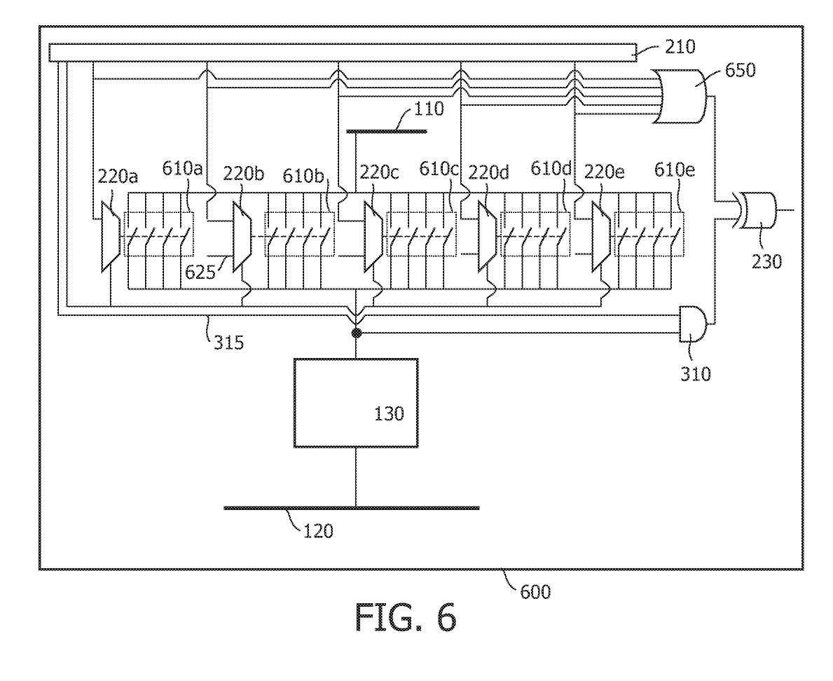

FIG. 6 shows a portion of an IC with yet another embodiment of the present invention.

It should be understood that the Figures are merely schematic and are not drawn to scale. It should also be understood that the same reference numerals are used throughout the Figures to indicate the same or similar parts.

The IC portion shown in FIG. 1 is an example of an IC for which the present invention can be used. IC 100 has a supply rail 110, e.g. a supply voltage (V_{DD}) rail, a further supply rail 120, e.g. ground, and functional blocks 130, which are coupled between the supply rail 110 and further supply rail 120. The functional blocks 130 can be selectively decoupled from the supply rail 110 via switches 115 and from the further supply rail 120 via switches 125 under control of the controller 140. The controller 140 is configured to control the switches 115 and/or the switches 125 individually, as indicated by the dashed lines, for enabling or disabling (i.e. power up or power down) individual functional blocks 130 when such blocks enter an active or inactive mode such as a stand-by mode. Such an IC is sometimes referred to as having multiple voltage islands, that is, multiple functional blocks, e.g. IP cores, having individually controllable voltage supplies.

Although FIG. 1 shows an IC having header and footer switches between the functional blocks 130 and both supply rails, it should be understood that alternative arrangements, e.g. with switches 115 between the functional blocks 130 and the supply rail 110 only, with switches 125 between the functional blocks 130 and the supply rail 120 only, or with multiple switches (not shown) in parallel between each functional block 130 and a supply rail are equally suited for application of the present invention, as will be explained in more detail below.

FIG. 2 shows a portion of an IC 200, which includes test hardware for testing the switch 115 between the power line 110 and the functional block 130. It will be appreciated that a single functional block 130 is shown for reasons of clarity only; typically, IC 200 will have a plurality of functional blocks 130 with at least a subset of those blocks being connected to their respective supply rails via one or more switches such as switch 115. The exact implementation of switch 115 is not of crucial importance to the present invention; the switch 115 may be realized by a suitable transistor, e.g. a pMOS transistor, or may be realized by other known switch implementations. However, for the sake of brevity, the following figures will be described with switch 115 implemented as a pMOS transistor.

To make transistor 115 testable, the IC 200 includes a multiplexer (MUX) 220, which has its output coupled to the gate of the transistor 115. The MUX 220 has a first input coupled to the previously described controller 140 for receiving the functional activation signal for the transistor 115, and a second input coupled to test controller 210, for receiving the test activation signal for the transistor 115. The appropriate input of MUX 220 is selected by a test enable signal, provided by the test controller 210 to the control terminal of the MUX 220. The test controller 210 may be implemented as a shift register arranged to provide both the test enable signal and the test activation signal to the MUX 220. The shift register may be coupled to a shadow register for capturing the complete bit pattern after it has been shifted into the shift register. This facilitates the shifting of bit patterns in parallel with testing a switch 115.

Alternatively, the test enable signal may be forwarded from an input (not shown) of the IC 200 to the MUX 220, or the test controller 210 may further comprise a, preferably IEEE 1149.1 compliant, TAP controller for providing the

MUX 220 with the test enable signal. The control terminal of the MUX 220 may be also coupled to a weak pull-up or pull-down signal generator, e.g. a pull-up or pull-down transistor, to ensure that in the absence of the test enable signal the appropriate input of the MUX 220 is selected.

The IC 200 further comprises a comparator 230 for comparing a reference signal from reference signal source 215 with a signal retrieved from the node 225 between the transistor 115 and the functional block 130. The reference signal may be provided by the test controller 210, or another suitable source. In FIG. 2, the reference signal is the same signal as the test activation signal of the transistor 115. This is by way on non-limiting example only; the reference signal may be a signal different to the test activation signal.

In FIG. 2, the comparator 230 is implemented as an exclusive OR (XOR) logic gate, but implementations using other types of logic gates, or more elaborate implementations, e.g. using a differential amplifier or other threshold comparison based circuits, with the threshold value being provided by the reference signal source 215, are equally feasible. The latter implementation may be beneficial if the resistive value of the switch 115 has to be tested as well. For instance, if the voltage drop over the switch 115 is too high to be acceptable, but too low to act as a hard stuck-at fault, a logic gate based comparator may not pick up this fault, and more refined detection based on predefined threshold voltages may be required.

The comparator 230 is arranged to provide a result signal on output 240. The output 240 may be provided to a shift register (not shown), in which the test results of the switches 115 of the various functional blocks of IC 200 are collected, or may be provided to an output pin (not shown) of the IC 200.

In test mode, two test patterns are provided in accordance with Table I.

TABLE I

| | | Reference Signal/ |
|---|---|---|
| Test pattern | Test Enable Signal | Test Activation Signal |
| 1 | 1 | 1 |
| 2 | 1 | 0 |

The first pattern selects the test activation signal input of the MUX 220, and provides this input with a logic high, thus switching off pMOS transistor 115. Consequently, the node 225 should be tied to the potential of the further power rail 120, i.e. grounded, and comparator 230 should produce a logic high due to the logic high value for the reference signal and the logic low value retrieved from the node 225. However, if the transistor 115 is stuck-at high, the node 225 will also produce a logic high, thus leading to the generation of a logic low by the comparator 230. Hence, this pattern detects a stuck-at high fault for the switch 115.

The second pattern also selects the test activation signal input of the MUX 220, but provides this input with a logic low, thus switching on pMOS transistor 115. Consequently, the node 225 should be tied to the potential of the power rail 110, i.e. V_{dd}, and comparator 230 should produce a logic high due to the logic low value for the reference signal and the logic high value retrieved from the node 225. However, if the transistor 115 is stuck-at low, the node 225 will also produce a logic low, thus leading to the generation of a logic low by the comparator 230. Hence, this pattern detects a stuck-at low fault for the switch 115.

It is advantageous to use these two test patterns in the given order. The start of the test sequence with the second test pattern would cause the functional block 130 to be charged up, and the subsequent application of the first test pattern would have to be delayed until the charges in the functional block 130 and associated node 225 have leaked away, thus unnecessarily extending the test time for the switch 115.

It will be appreciated that the use of the aforementioned test patterns always drives the comparator 230 to a logic high for a correctly functioning transistor 115. However, if the output of the comparator 230 is stuck-at high, an incorrectly functioning transistor 115 cannot be detected. For this reason, it is desirable to also be able to drive the output of the comparator 230 to a logic low for a correctly functioning transistor 115, in order to be able to pick up the stuck-at fault at the output 240.

This is realized in the IC 300 shown in FIG. 3. A logic AND gate 310 has been inserted in the conductive path between the node 225 and the comparator 230, with the second input of the AND gate 310 being coupled to a further reference signal source 315. The further reference source 315 may be coupled to the test controller 210 for receiving the further reference signal. This provides an additional test point to the IC 300, which facilitates the detection of a stuck-at high fault at the output 240. For instance, by providing a test pattern in which the test enable signal is high, and both the reference and further reference signals are low, the output 240 can be forced to a logic low, thus facilitating the detection of a stuck-at high fault at the output 240. It will be obvious to the skilled person that the additional test point of the IC 300 may be implemented in other ways, e.g. by using other types of logic gates.

FIG. 4 shows an embodiment of a test solution according to the present invention for an IC having both header switches 115 and footer switches 125 between the respective supply rails 110 and 120 and the functional blocks 130. In addition to the arrangement of FIG. 3, the IC 400 of FIG. 4 includes a further MUX 420, which has its output coupled to the control terminal of the switch 125, e.g. the gate of an nMOS transistor. The further MUX 420 has a first input coupled to the previously described controller 140 for receiving the functional activation signal for the transistor 125, and a second input coupled a further test controller 410, for receiving a further test activation signal for the transistor 125. The appropriate input of the further MUX 420 is selected by a test enable signal, provided by the further test controller 410 to the control terminal of the further MUX 420.

The further test controller 410 may be implemented as a separate shift register arranged to provide both the test enable signal and the further test activation signal to the further MUX 420. Alternatively, the test controller 210 may also include the further test controller 410, and may be implemented as a single shift register under control of a TAP controller. The advantage of having separate test controllers, e.g. separate shift registers, is that shorter bit patterns can be used, which will reduce the overall test time required for testing the switches 115 and 125. However, an additional test data input channel (not shown) has to be present on the IC 400 to facilitate this.

The IC 400 further comprises an additional comparator 430, again implemented as an XOR gate, although the aforementioned alternatives in the description of FIG. 2 are equally feasible, having a first input coupled to a further node 425 between the functional block 130 and the transistor 125, and a second input coupled to a second further reference signal source 415, which may be coupled to the further test controller 410. Optionally, an additional test point, e.g. an AND gate 450 may be present in the path between the further node 425 and the comparator 430, with the AND gate 450 having an input coupled to a third further reference signal source 455 to facilitate the detection of a stuck-at high fault at the output 440 of the comparator 430, as previously explained.

In FIG. 4, the second further reference signal and the further test activation signal are the same signals, although this is not required. An optional second further MUX 460 has a first input coupled to output 240 and a second input coupled to output 440, and has an output coupled to an output pin 470 of the IC 400. Alternatively, the output of the second further MUX 460 may be coupled to a shift register (not shown) to facilitate the testing of multiple switches of multiple functional blocks in parallel and shifting out the test results in a serial fashion. The second further MUX 460 may have its control terminal coupled to the test controller 210, as shown, or to the further test controller 410 or to a TAP controller (not shown) for controlling the test controller 210 and/or the further test controller 410.

The outputs of the comparators 230 and 430 may also be directly coupled to respective outputs of the IC 200 or to a shift register. This facilitates testing of the switches 115 and 125 in parallel, although it will be appreciated that because these switches are conductively coupled via functional block 130, this introduces restrictions on the test patterns that can be used simultaneously for the respective switches. For this reason, the sequential testing of switch 115 and further switch 125 in combination with the presence of second further MUX 460 is preferred.

FIG. 5 shows a test arrangement for an IC 500 having segmented power switches 115 between the supply rail 110 and the functional block 130. The use of segmented power switches, i.e. a number of switches in parallel between the supply rail 110 and the functional block 130 has the advantage that smaller switches can be used compared to an IC having a single power switch 115. Also, gradual power-up of a functional block 130 is facilitated, thus avoiding drops in the power supply voltage caused by sudden power-up of functional blocks 130.

The IC 500 has a first subset 510a and a second subset 510b of four switches 115, e.g. pMOS transistors 115. The number of switches 115 per subset and the number of subsets is by way of non-limiting example only; other numbers are equally feasible. The transistors in the first subset 520a have their gates coupled to an output of a first MUX 220a, and the transistors in the second subset 510a have their gates coupled to an output of a second MUX 220b. The control terminals of the first and second MUX 220a and 220b are responsive to the test enable signal, and have a first input coupled to respective functional activation signals from controller 140 and a second input coupled to respective test activation signals from the test controller 210. The respective test activation signals are also fed to an OR gate 550, which indicates the activation of at least one subset of switches 115. Comparator 230 has an input coupled to an output of the OR gate 550 and another input coupled to the node 225, optionally via AND gate 310 to facilitate detection of a stuck-at high fault at the output 240 of the comparator 230, as previously explained.

In FIG. 6, the IC 600 has five subsets 610a-e of switches 115, with the gates of the switches per subset being controlled by respective multiplexers 220a-e. The control terminal of each MUX 220a-e is responsive to the test enable signal, and each MUX 220a-e is configured to receive a respective test activation signal from the test controller 210 and a respective functional activation signal from the controller 140 (not shown in FIG. 6). Due to the fact that five subsets 610a-e are present, IC 600 comprises a five-input OR gate 650 to indicate the provision of at least one test activation signal to a subset of switches 115. Generally, the number of inputs of the OR gates 550 and 650 matches the number of subsets of switches 115. At this point, it is emphasized that OR gates 550 and 650 have been used as non-limiting examples of suitable logic gates. The use of other types of logic gates, e.g. AND gates, is equally feasible.

In the test arrangements of FIGS. 5 and 6, care has to be taken that during test the potential in node 225 is at least a minimum value of Vdd (V_{ddmin}), e.g. V_{dd}/2, to ensure that the comparator 230, e.g. XOR gate 230, provides the correct evaluation of the subset(s) under test. In other words, in case the potential at the node 225 has to be at least V_{ddmin}, the on-resistance of an active subset may not exceed the on-resistance of the functional block 130. This has to be considered at the design stage of the ICs 500 and 600, e.g. by appropriately selecting the number of switches 115 per subset, and by appropriately selecting the number of subsets activated per test vector.

Moreover, the resistance of the functional block 130, i.e. its activity, has to be kept constant during test to avoid fluctuations in the potential at the node 225, which could cause the potential value to drop below V_{ddmin}. This can for instance be achieved by shifting all-1 or all-0 test vectors through the internal scan chains (not shown) of the functional block 130, which keeps the functional block 130 in a steady state, by gating the functional clock (not shown) of the functional block 130 during power switch test. The actual resistance value of a functional block 130 determines the number of switches 115 that are selected (activated) during test.

Table II shows the test patterns that may be applied to the test arrangement of IC 500. MUX 220a and MUX 220b have their test activation input selected by the test enable signal, and further reference signal source 315 is kept at a logic high.

TABLE II

| Test activation 220a | Test activation 220b | Correct output 240 |
|---|---|---|
| 1 | 1 | 1 |
| 0 | 1 | 0 |
| 1 | 0 | 0 |

For the switches 115 being implemented as pMOS transistors, the 1,1 pattern disables the switches in both subset 510a and subset 510b. OR gate 550 should produce a logic high at its output whereas AND gate 310 should produce a logic low at its output. Consequently, the output 240 should produce a logic high (‘1’). However, if one of the switches in the subset 510a or 510b is stuck-at a logic high, the potential at the node 225 will be high, causing the AND gate 310 to produce a logic high. Consequently, the comparator 230 will produce a logic low as an indication of this fault.

The test patterns 0,1 and 1,0 detect stuck-at logic low faults in the respective enabled subsets. For instance, for the 0,1 pattern, the pMOS transistors of the subset 510a are enabled whereas the pMOS transistors of the subset 510b are disabled. OR gate 550 produces a logic high, and if no stuck-at low fault is present in subset 510a, the node 225 will be at a high enough potential to cause AND gate 310 to produce a logic high. Consequently, the output 240 of the comparator 230 will carry a logic low (‘0’). A stuck-at low fault in enabled subset 510a will prevent the node 225 reaching a high enough potential value, resulting in AND gate 310 producing a logic low. This causes a logic high (‘1’) on the output 240, thus indicating the presence of said fault.

It is also possible to test more than one subset of switches at the same time. This is demonstrated in Table III, in which some test patterns applicable to IC 600 are given. For these test patterns, for all multiplexers 220a-e the test activation signal input is selected and further reference signal source 315 is kept at a logic high.

TABLE III

| | Test | Test | Test | Test | Test | Correct |
|---|---|---|---|---|---|---|
| Pattern | activation 220a | activation 220b | activation 220c | activation 220d | activation 220e | output 240 |
| A | 0 | 0 | 0 | 1 | 1 | 0 |
| B | 1 | 0 | 0 | 0 | 1 | 0 |
| C | 1 | 1 | 0 | 0 | 0 | 0 |
| D | 0 | 1 | 1 | 0 | 0 | 0 |
| E | 0 | 0 | 1 | 1 | 0 | 0 |
| F | 0 | 0 | 1 | 1 | 1 | 1 |
| G | 1 | 0 | 0 | 1 | 1 | 1 |
| H | 1 | 1 | 0 | 0 | 1 | 1 |
| I | 1 | 1 | 1 | 0 | 0 | 1 |

By way of non-limiting example, it is assumed that IC 600 requires at least three of the subsets 610a-e to be enabled for the node 225 to reach at least V_{dd}/2. Thus, to be able to find a stuck-at low fault in an enabled subset, the applied test patterns must enable at least three of the subsets 610a-e. For instance, for pattern A, the node 225 should reach at least V_{dd}/2, because the pMOS transistors in at least three subsets, i.e. subsets 610a-c are enabled. If the subsets 610a-c are fault-free, the outputs of OR gate 650 and AND gate 310 will carry a logic high (‘1’), causing a logic low (‘0’) at output 240 of comparator 230 implemented as an XOR gate. If, however, a stuck-at low is present in any of the enables subsets 610a-c, the node 225 will not reach V_{ddmin}, and the AND gate 310 will produce a logic low, causing output 240 to go high, thus indicating the presence of said fault.

In order to identify the subset causing such a fault, the test pattern A may be shifted through the test controller 210 in a sliding window fashion, as indicated by test patterns B-E. For instance, if the stuck-at low is located in subset 610b, patterns A and B will produce a faulty test output, whereas pattern C and D will not. From this information, it can be concluded that the stuck-at low fault resides in subset 610b.

Similarly, stuck-at high faults can be found by simultaneously enabling a smaller number of subsets 510a-e than required for the node 225 to reach at least V_{ddmm}. For instance, for pattern F, only subset 610a and 610b are enabled, which is not enough for node 225 to reach V_{ddmin} if these subsets are fault-free. Consequently, AND gate 310 will produce a logic low, OR gate 650 will produce a logic high, and the output 240 of the comparator 230 will carry a logic high as well. However, if a stuck-at high is present in at least one of the subsets 610a and 610b, the node 225 will reach V_{ddmin}, causing the output of AND gate 310 to go high and the output 240 to go low, thus indicating the presence of said fault. The fault can be assigned to a single subset by applying the previously explained sliding window approach.

This approach is particularly useful when it is not feasible to test each subset 610a-e individually, e.g. because the number of subsets is too large, because the sliding window approach reduces the number of required test vectors to detect a stuck-at fault in any segment.

For an IC having m subsets 610, with m being a positive integer of at least value 3, the number of subsets that need to be turned on simultaneously is k, with k being an integer having a value 1≦k≦m. The sliding window approach can be used to test a given (m, k) segmented power switch. Just to test on/off functionality of a power switch, only two patterns, with all 1's and all ' 0 are sufficient. However, for maximal diagnosis of individual failing segments, the window size w should be equal to k. Based on this, the number of test patterns IPA required for a given (m, k) power switch can be calculated as follows.

|Pₘ=m+1, ∀k=1, or k=m

|Pₘ|=2m, ∀1<k<m

It is important to note that the number of patterns does not depend on the overlap q between the windows for two subsequent patterns. Basically, p1 distinct patterns with k 0's and (m−k) 1's are required to check whether there is a complete open in any of the segments, while p2 distinct patterns with (k−1) 0's and (m−k+1) 1's are required to check a complete short in any of the segments. To faciliate testing the segments using the sliding window approach, the patterns should contain uninterrupted runs of required 0's or 1's. The required pattern set for a given (m, k), may be generated by starting with a m-bit vector with the first k bits as ‘0’s and (m−k) bits as ‘1’s. To obtain the next vector, the sequence of k ‘0’ bits need to be circularly shifted to the right by one position. The shift operation needs to be carried out m−1 times to get p1 distinct test patterns. Similarly, for p2 patterns, the pattern generation is started with an m-bit vector with the first k−1 bits as ‘0’s and (m−k+1) bits as ‘1’s.

For the case with k=1, p1 is m, while p2 is 1 as it corresponds to a pattern with all 1's. Similarly, for the case with k=m, p1 is 1, while p2 is m. Therefore, the total number of patterns for these two boundary cases is m+1. For all other cases with 1<k<m, both p1 and p2 are m, therefore, 2m patterns are required to test power switches. It is noted that for certain values of k and m, it may not be possible to identify individual failing segments. For example, in cases with k=1 and m>1, it is not possible to detect which of the m segments has a possible short. Similarly, for the cases with k=m, segments cannot be diagnosed individually for a possible open. For maximum diagnosis of shorts in the segments, the value of k should be m−1; while for maximum diagnosis of opens in segments, the value of k should be 1.

FIGS. 2, 3, 5 and 6 depict a test solution for an IC having (header) switches 115 between a supply rail 110 and its functional blocks 130. It will be obvious that those test solutions are equally valid for an IC having (footer) switches 125 between its functional blocks 130 and a further supply rail 120

In FIGS. 2-6, the power switches 115 and/or 125 under test have been enabled by the application of a dedicated test activation signal via respective multiplexers. However, it is emphasized that in a test mode, these switches may also be enabled by the functional activation signals from controller 140. In this case, the dedicated test activation signals do not have to be provided to the switches 115 and/or 125, and the aforementioned multiplexers, i.e. multiplexers 220 and/or 420, may be omitted. This can for instance be realized by making the controller 140 responsive to the test activation signals from test controller 210 under control of the test enable signal.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The invention can be implemented by means of hardware comprising several distinct elements. In the device claim enumerating several means, several of these means can be embodied by one and the same item of hardware. The mere fact that certain measures are recited in mutually different dependent claims does not indicate that a combination of these measures cannot be used to advantage.

1. An integrated circuit comprising:
a functional block conductively coupled to a supply rail via switching means;
selection means responsive to a test enable signal for activating the switching means; and
evaluation means having a first input coupled to a reference signal source and having a second input coupled to a node between the switching means and the functional block for evaluating the behaviour of the switching means based on the reference signal and a signal from the node.

2. An integrated circuit as claimed in claim 1, wherein the evaluation means comprise a comparator for comparing the reference signal with the signal from the node.

3. An integrated circuit as claimed in claim 2, wherein the comparator is implemented as a logic gate.

4. An integrated circuit as claimed in claim 3, further comprising a further logic gate comprising a first input coupled to the node, a second input coupled to a further reference signal source, and an output coupled to an input of the logic gate.

5. An integrated circuit as claimed in claim 1, wherein the evaluation means comprise a shift register coupled to an output of the integrated circuit.

6. An integrated circuit as claimed in claim 1, wherein the selection means comprise a multiplexer having a first input for receiving a test activation signal, a second input for receiving a functional activation signal and an output coupled to the selection means.

7. An integrated circuit as claimed in claim 1, wherein the switching means comprises a plurality of transistors in parallel between the supply rail and the functional block, the selection means being coupled to the gates of each of the respective transistors.

8. An integrated circuit as claimed in claim 7, wherein the selection means comprise a plurality of multiplexers responsive to the test enable signal, each multiplexer having:
a first input for receiving a test activation signal;
a second input for receiving a functional activation signal, and
an output coupled to a subset (610a-e) of the plurality of transistors.

9. An integrated circuit as claimed in any of the preceding claims, further comprising:
test configuration means for providing the test enable signal to the selection means, the test configuration means comprising the reference signal source.

10. An integrated circuit as claimed in claim 9, wherein the test configuration means are implemented as a shift register.

11. An integrated circuit as claimed in claim 1, wherein:
the integrated circuit comprises a plurality of functional blocks, each coupled to the supply rail via respective switching means;
the selection means comprise a controller for selecting subsets of the respective switching means during functional mode of the integrated circuit, the controller being responsive to a bit pattern for selecting said subsets in a test mode of the integrated circuit.

12. An integrated circuit as claimed any of the preceding claims, wherein the functional block is coupled to a further supply rail via further switching means, the integrated circuit further comprising:
further selection means responsive to the test enable signal for activating the further switching means and
further evaluation means having a first input coupled to a second further reference signal source and having a second input coupled to a further node between the further switching means and the functional block for evaluating the behaviour of the further switching means based on the second further reference signal and a signal from the further node.

13. An integrated circuit as claimed in claim 12, wherein the further selection means are responsive to further test configuration means.

14. An integrated circuit as as claimed in claim 9, further comprising a test output and test output selection means having a first input coupled to an output of the evaluation means, a second input coupled to an output of the further evaluation means (430) and an output coupled to the test output.

15. A method for testing an integrated circuit comprising:
a functional block conductively coupled to a supply rail via switching means
selection means responsive to a test enable signal for activating the switching means; and
evaluation means having a first input coupled to a reference signal source and having a second input coupled to a node between the switching means and the functional block for evaluating the behaviour of the switching means based on the reference signal and a signal from the node, the method comprising:
providing the test enable signal to the selection means;
providing the reference signal to the evaluation means;
retrieving the signal from the node; and
determining a test result from the reference signal and the signal from the node.

16. A method as claimed in claim 15, wherein determining said test result comprises comparing the reference signal to the signal from the node.

17. A method as claimed in claim 15, wherein the switching means comprise a plurality of transistors in parallel between the supply rail and the functional block, the selection means being coupled to the gates of each of the respective transistors, the selection means comprising a plurality of multiplexers responsive to the test enable signal, each multiplexer having:
a first input for receiving a test activation signal;
a second input for receiving a functional activation signal, and
an output coupled to a subset of the plurality of transistors; the method further comprising:
providing the test activation signal to a subset of said multiplexers;
determining the test result;
providing the test activation signal to a further subset of said multiplexers, the subset and the further subset being partially overlapping; and
determining a further test result from the reference signal and the signal from the node.

18. A method as claimed in claim 17, further comprising locating a fault in one of the subsets of the plurality of transistors based on a difference between the test result and the further test result.
